(19) United States
(12) Patent Application Publication
(10) Pub. No.: US 2024/0128173 A1
(43) Pub. Date: Apr. 18, 2024

(54) SEMICONDUCTOR PACKAGE AND METHOD OF FABRICATING THE SAME

(71) Applicant: Samsung Electronics Co., Ltd., Suwon-si (KR)

(72) Inventors: Ji-Yong Park, Suwon-si (KR); Jong Bo Shim, Suwon-si (KR); Dae Hun Lee, Suwon-si (KR); Choong Bin Yim, Suwon-si (KR)

(21) Appl. No.: 18/320,456

(22) Filed: May 19, 2023

(30) Foreign Application Priority Data
Oct. 17, 2022 (KR) 10-2022-0133272
Nov. 16, 2022 (KR) 10-2022-0154062

(51) Int. Cl. H01L 23/498; H01L 21/56; H01L 23/00; H01L 23/12; H01L 23/31; H01L 23/367; H01L 25/065

(52) U.S. Cl. CPC H01L 23/49816; H01L 21/563; H01L 21/565; H01L 23/12; H01L 23/3128; H01L 23/3135; H01L 23/3675; H01L 24/13; H01L 24/14; H01L 24/73; H01L 25/0657; H01L 2224/13025; H01L 2224/1403; H01L 2224/14131

(57) ABSTRACT

A semiconductor package includes a first package substrate having a first region and a second region, which do not overlap each other, a first connection element having a first height on the first region, a first semiconductor chip having a second height connected to the first connection element, a second connection element having a third height on the second region, a third connection element having a fourth height on the second connection element and electrically connected to the second connection element, a second package on the third connection element, the second package including a second package substrate and a second semiconductor chip, and a first mold layer covering at least a portion of the first semiconductor chip, covering at least a portion of the second connection element, covering the first package substrate, exposing upper surfaces of the first semiconductor chip and the second connection element, and having a fifth height.

### CROSS-REFERENCE TO RELATED APPLICATION

This application claims priority under 35 U.S.C. 119 from Korean Patent Application No. 10-2022-0133272, filed on Oct. 17, 2022, and Korean Patent Application No. 10-2022-0154062, filed on Nov. 16, 2022, in the Korean Intellectual Property Office, the contents of which are herein incorporated by reference in their entirety.

### BACKGROUND

The present disclosure relates to a semiconductor package and a method of fabricating the same.

With the development of electronic industry, demands for high functionality, high-speed and miniaturization of electronic components have increased. In response to this trend, a package-on-package (POP) type semiconductor package in which a package is stacked on another package may be used. In order to improve heat dissipation characteristics of the semiconductor package, a thickness of a semiconductor chip packaged on a package may be increased. However, since a structure of the POP type semiconductor package has limitation in increasing the thickness of the semiconductor chip, studies for package stack technologies capable of stacking two or more semiconductor packages in a stable structure and at the same time increasing the thickness of the semiconductor chip are ongoing.

### SUMMARY

An object of the present disclosure is to provide a semiconductor package having improved reliability.

Another object of the present disclosure is to provide a method of fabricating a semiconductor package having improved reliability.

According to some aspects of the present disclosure, there is a provided semiconductor package including a first package substrate having a first region and a second region, which do not overlap each other, a first connection element having a first height on the first region, a first semiconductor chip having a second height connected to the first connection element, a second connection element having a third height on the second region, a third connection element having a fourth height on the second connection element and electrically connected to the second connection element, a second package disposed on the third connection element, the second package including a second package substrate and a second semiconductor chip, and a first mold layer covering at least a portion of the first semiconductor chip, covering at least a portion of the second connection element, covering at least a portion the first package substrate, exposing an upper surface of the first semiconductor chip and an upper surface of the second connection element, and having a fifth height.

According to some aspects of the present disclosure, there is a provided semiconductor package comprising semiconductor package including a first package substrate, a first semiconductor chip on the first package substrate, a first connection element horizontally spaced apart from the first semiconductor chip and on the first package substrate, a second connection element on the first connection element and electrically connected to the first connection element, a second disposed on the second connection element, the second package including a second package substrate and a second semiconductor chip, and a mold layer on the first package substrate and exposing an upper surface of the first semiconductor chip and an upper surface of the first connection element, wherein the second semiconductor chip does not vertically overlap the first semiconductor chip.

According to some aspects of the present disclosure, there is a provided method of fabricating a semiconductor package, the method including mounting a first semiconductor chip on a first region of a first package substrate, positioning a first connection element on a second region of the first package substrate that is separate from the first region, forming a first mold layer covering at least a side of the first semiconductor chip and at least a side of the first connection element, exposing an upper surface of the first semiconductor chip and an upper surface of the first connection element by grinding the first mold layer, and mounting, on the first connection element, a second connection element electrically connected to the first connection element and a second package which is electrically connected to the second connection element and includes a second package substrate and a second semiconductor chip.

The objects of the present disclosure are not limited to those mentioned above and additional objects of the present disclosure, which may not be mentioned herein, will be clearly understood by those skilled in the art from the following description of the present disclosure.

### BRIEF DESCRIPTION OF THE DRAWINGS

These and/or other aspects will become apparent and more readily appreciated from the following description of the embodiments, taken in conjunction with the accompanying drawings in which:

FIG. 1 is an example plan view illustrating a semiconductor package according to some embodiments.

FIG. 2 is a cross-sectional view taken along line I-I of FIG. 1.

FIG. 3 is an enlarged view illustrating a portion II of FIG. 2.

FIGS. 4 and 5 are example views illustrating a semiconductor package according to some embodiments.

FIG. 6 is an enlarged view illustrating a portion III of FIG. 5.

FIG. 7 is an example plan view illustrating a semiconductor package according to some embodiments.

FIG. 8 is a cross-sectional view taken along line IV-IV of FIG. 7.

FIGS. 9 and 10 are example views illustrating a semiconductor package according to some embodiments.

FIG. 11 is a flowchart illustrating a method of fabricating a semiconductor package according to some embodiments.

FIGS. 12 to 19 are views illustrating intermediate steps to describe a method of fabricating a semiconductor package according to some embodiments.

FIG. 20 is an enlarged view illustrating a portion V of FIG. 19.

FIG. 21 is an enlarged view illustrating a portion VI of FIG. 19.

FIGS. 22 and 23 are views illustrating intermediate steps to describe a method of fabricating a semiconductor package according to embodiments.

FIG. 24 is a view illustrating a semiconductor package and a main board according to some embodiments.

FIGS. 25 and 26 are views illustrating an electronic device including a semiconductor package according to some embodiments.

### DETAILED DESCRIPTION

Hereinafter, a semiconductor package and a method of fabricating the same according to some embodiments will be described with reference to the accompanying drawings.

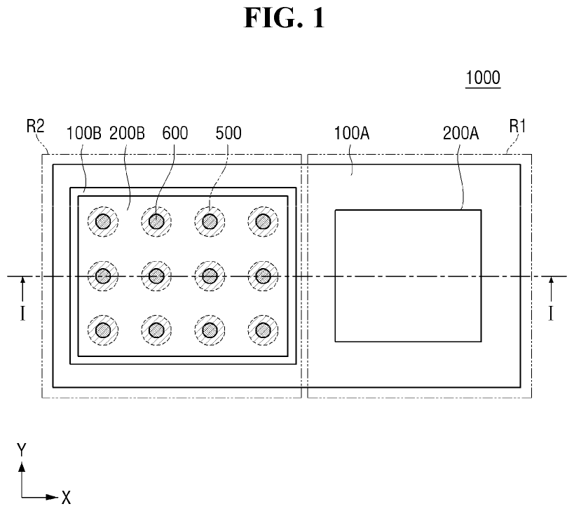

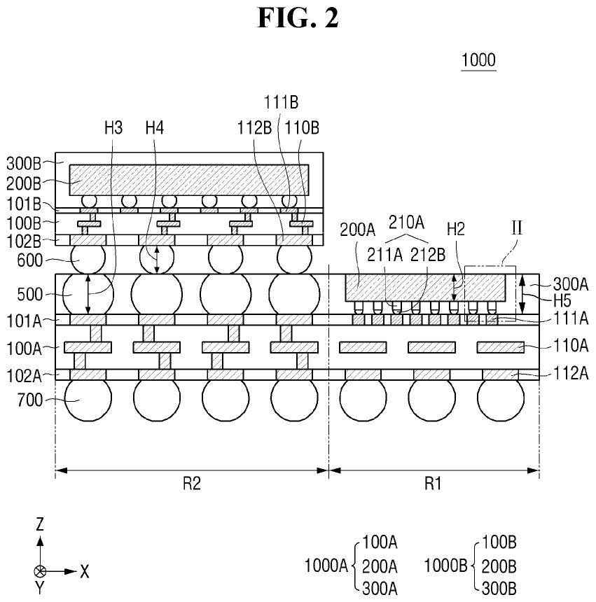

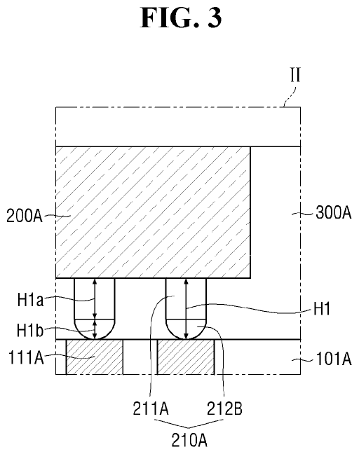

FIG. 1 is an example plan view illustrating a semiconductor package according to some embodiments. FIG. 2 is a cross-sectional view taken along line I-I of FIG. 1. FIG. 3 is an enlarged view illustrating a portion II of FIG. 2.

Referring to FIGS. 1 and 2, a semiconductor package 1000 according to some embodiments may include a first package 1000A, a second package 1000B, a first connection element 210A, a second connection element 500 and a third connection element 600. In detail, the first package 1000A may include a first package substrate 100A, a first semiconductor chip 200A, and a first mold layer 300A. The second package 1000B may include a second package substrate 100B, a second semiconductor chip 200B, and a second mold layer 300B.

The first package substrate 100A may be a printed circuit board (PCB) or a ceramic substrate, but is not limited thereto. When the first package substrate 100A is a PCB, the first package substrate 100A may be made of at least one material selected from phenol resin, epoxy resin and polyimide. The first package substrate 100A may include at least one material selected from tetrafunctional epoxy, polyphenylene ether, epoxy/polyphenylene oxide, bismaleimide triazine (BT), thermount, cyanate ester and liquid crystal polymer.

The first package substrate 100A may include a resin impregnated in a core material, such as a glass fiber, a glass cloth or a glass fabric, together with an inorganic filler, for example, a prepreg, an Ajinomoto Build-up Film (ABF), FR-4, or Bismaleimide Triazine (BT).

A surface of the first package substrate 100A may be covered by a solder resist. That is, a first upper passivation layer 101A and a first lower passivation layer 102A, which are formed on surfaces of the first package substrate 100A, may be solder resists. The first upper passivation layer 101A and the first lower passivation layer 102A may include, for example, a photoimageable dielectric material (PID), but the present disclosure is not limited thereto.

A first wiring pattern 110A may be formed inside the first package substrate 100A. The first wiring pattern 110A may include a connection structure 700 and a plurality of wiring vias electrically connecting components disposed on the first package substrate 100A. The first wiring pattern 110A may include at least one of copper (Cu), aluminum (Al), silver (Ag), tin (Sn), gold (Au), nickel (Ni), lead (Pb), titanium (Ti) or alloys thereof, but is not limited thereto.

In FIG. 2, three layers composed of a first upper passivation layer 101A, a first package substrate 100A and a first lower passivation layer 102A are illustrated, but this is for convenience of description. For example, in some embodiments, four or more multiple layers may be configured so that wiring patterns of multiple layers may be formed therein.

In some embodiments, at least one passive element (e.g., resistor or capacitor) may be installed inside the first package substrate 100A or on the surface of the first package substrate 100A. The first upper passivation layer 101A and a first upper pad 111A may be formed on an upper surface of the first package substrate 100A. The first upper pad 111A may be disposed between the first upper passivation layer 101A and the first package substrate 100A. The first upper passivation layer 101A may be formed on the first package substrate 100A to expose the first upper pad 111A. An upper surface of the first upper passivation layer 101A and an upper surface of the first upper pad 111A may be coplanar or substantially coplanar. But the present disclosure is not limited thereto. In some embodiments, the upper surface of the first upper passivation layer 101A may be higher in Z-axis direction than the upper surface of the first upper pad 111A. In this case, a portion of the first upper pad 111A may be exposed by the first upper passivation layer 101A to be connected to the second connection element 500.

The first lower passivation layer 102A and a first lower pad 112A may be formed on a lower surface of the first package substrate 100A. The first lower pad 112A may be disposed between the first lower passivation layer 102A and the first package substrate 100A. The first lower passivation layer 102A may be formed on the first package substrate 100A to expose the first lower pad 112A. A lower surface of the first lower passivation layer 102A and a lower surface of the first lower pad 112A may be coplanar or substantially coplanar. But the present disclosure is not limited thereto. In some embodiments, the lower surface of the first lower passivation layer 102A may be higher in the opposite direction of the Z-axis than the lower surface of the first lower pad 112A. In this case, a portion of the first lower pad 112A may be exposed by the first lower passivation layer 102A to be connected to the connection structure 700.

In some embodiments, the connection structure 700 may be formed on a lower surface of the first lower passivation layer 102A or a lower surface of the first lower pad 112A. The connection structure 700 may be attached to the first lower pad 112A. The connection structure 700 may electrically connect the first wiring pattern 110A to an external device. Therefore, the connection structure 700 may provide an electrical signal to the first wiring pattern 110A, or may provide an electrical signal provided from the first wiring pattern 110A to the external device.

The connection structure 700 may be, for example, a solder bump, but is not limited thereto. The connection structure 700 may have various shapes such as a land, a ball, a pin and a pillar. Various modifications may be made in the number, interval, arrangement shape, etc. of connection structures 700 depending on the design.

The connection structure 700 may include at least one of tin (Sn), indium (In), lead (Pb), zinc (Zn), nickel (Ni), gold (Au), silver (Ag), copper (Cu), antimony (Sb), bismuth (Bi) or their combination, but the present disclosure is not limited thereto.

The first package substrate 100A may have a first region R1 and a second region R2, which do not overlap each other in view of a plane or in plan view. The first semiconductor chip 200A may be disposed on the first region R1 of the first package substrate 100A. The first semiconductor chip 200A may be connected to the first upper pad 111A of the first upper passivation layer 101A and thus electrically connected to the first wiring pattern 110A.

For example, the first semiconductor chip 200A may include an integrated circuit IC in which hundreds to millions of semiconductor devices are integrated in one chip. The first semiconductor chip 200A may be an application processor (AP) such as a Central Processing Unit (CPU), a Graphic Processing Unit (GPU), a Field Programmable Gate Array (FPGA), a digital signal processor, an encryption processor, a microprocessor and a microcontroller, or may be a logic chip such as a System On Chip (SOC).

In some embodiments, the first semiconductor chip 200A may be mounted on the first region R1 of the first package substrate 100A by a flip chip bonding method. The first semiconductor chip 200A may be connected to the first connection element 210A. For example, the first connection element 210A may be formed between an upper surface of the first upper passivation layer 101A and a lower surface of the first semiconductor chip 200A. The first connection element 210A may electrically connect the first package substrate 100A with the first semiconductor chip 200A.

In some embodiments, the first connection element 210A may be implemented as a bump, but the disclosure is not limited thereto, and the first connection element 210A may be implemented as a solder ball that includes a conductive material. When the first connection element 210A is implemented as a bump, the first connection element 210A may include a pillar layer 211A and a solder layer 212B. The pillar layer 211A may protrude from the lower surface of the first semiconductor chip 200A. The pillar layer 211A may include, for example, copper (Cu), a copper alloy, nickel (Ni), palladium (Pd), platinum (Pt), gold (Au), cobalt (Co) and their combination, but is not limited thereto.

The solder layer 212B may connect the pillar layer 211A with the first package substrate 100A. For example, the solder layer 212B may be electrically connected to some of the first upper pads 111A. The solder layer 212B may be, for example, spherical or elliptical, but is not limited thereto.

The solder layer 212B may include, for example, tin (Sn), indium (In), bismuth (Bi), antimony (Sb), copper (Cu), silver (Ag), zinc (Zn), lead (Pb) or their combination, but is not limited thereto. Various modifications may be made in the number, interval, arrangement shape, etc. of first connection elements 210A depending on the design. Referring to FIG. 3, when the first connection element 210A is implemented as a bump, a height H1 of the first connection element 210A may correspond to a sum of a height H1a of the pillar layer 211A and a height H1b of the solder layer 212B.

The second connection element 500 may be disposed on the second region R2 of the first package substrate 100A. In some embodiments, the second connection element 500 may be horizontally spaced apart from the first semiconductor chip 200A in view of a plane (e.g., X-Y plane) and disposed on the first package substrate 100A. The second connection element 500 may be, for example, a solder ball, but is not limited thereto. The second connection element 500 may have various shapes such as a bump, a land, a pin and a pillar. Various modifications may be made in the number, interval, arrangement shape, etc. of second connection elements 500 depending on the design. Hereinafter, the case that the second connection element 500 has a solder ball shape will be described as an example.

In some embodiments, the second connection element 500 may have a shape in which a portion of its upper surface is partially ground. For example, after the first mold layer 300A covering at least a portion of the first semiconductor chip 200A or the second connection element 500 and covering the first package substrate 100A is formed on the first package substrate 100A, as the first mold layer 300A is ground, a portion of the upper surface portion of the second connection element 500 and a portion of the upper surface portion of the first semiconductor chip 200A may be ground together. Upper surfaces of the first mold layer 300A, the second connection element 500, and the first semiconductor chip 200A may be coplanar or substantially coplanar.

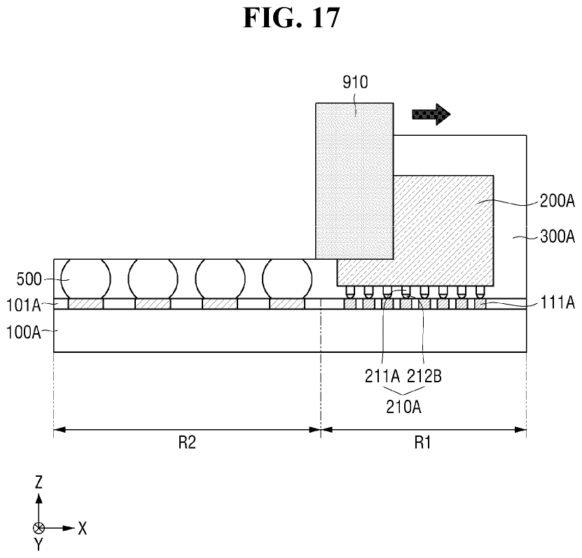

Therefore, a sum of a height H1 of the first connection element 210A and a height H2 of the first semiconductor chip 200A may be the same as a height H3 of the second connection element 500. Also, the height H3 of the second connection element 500 may be the same as a height H5 of the first mold layer 300A. A grinding operation of the first mold layer 300A, a portion of the upper surface portion of the second connection element 500 and a portion of the upper surface portion of the first semiconductor chip 200A will be described below with reference to FIG. 17.

The second connection element 500 may serve as a connection structure and a support structure for mounting the second package 1000B on a side of the first semiconductor chip 200A. That is, in order to realize a side-by-side stack package structure in some embodiments, the second connection element 500 may be disposed on the second region R2 that does not overlap the first region R1 on which the first semiconductor chip 200A is mounted, and the first mold layer 300A covering the upper surface of the second connection element 500 may be ground to expose the upper surface of the second connection element 500 so that the second package 1000B may be mounted on the exposed upper surface of the second connection element 500.

As described above, in some embodiments, the second connection element 500 is disposed between the first package substrate 100A and the third connection element 600, so that a height H4 of the third connection element 600 may be set to be lower than the case that the second package 1000B is directly mounted on the first package substrate 100A. For example, when the third connection element 600 is implemented as a solder ball, a size of the solder ball may be set to be small. Therefore, a larger number of third connection elements 600 may be disposed on a lower surface of the second package substrate 100B, and as a result, In-Out (I/O) of the second package 1000B may be increased.

In some embodiments, the first mold layer 300A covering at least a portion of the first semiconductor chip 200A or the second connection element 500 and covering the first package substrate 100A may be formed on the upper surface of the first package substrate 100A. The first mold layer 300A may fill or be in a space among the first package substrate 100A, the first semiconductor chip 200A, the first connection element 210A and the second connection element 500. Therefore, the first mold layer 300A may cover or be on the first package substrate 100A, the first semiconductor chip 200A, the first connection element 210A and the second connection element 500. In some embodiments, the first mold layer 300A may cover or surround the sides of the first semiconductor chip 200A and the second connection element 500 and may not cover the upper surfaces of the first semiconductor chip 200A and the second connection element 500. That is, the upper surfaces of the first semiconductor chip 200A and the second connection element 500 may be exposed by the first mold layer 300A.

The first mold layer 300A may include an insulating polymer material such as an epoxy molding compound (EMC). The first mold layer 300A may include a thermosetting resin such as an epoxy resin, a thermoplastic resin such as polyimide, or a resin including a reinforcing material, such as a filler, in the thermosetting resin or the thermoplastic resin, for example, ABF, FR-4, BT resin, etc.

The filler may be at least one selected from a group consisting of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and zircon calcium (CaZrO₃), but its material is not limited thereto and may include a metal material and/or an organic material.

The third connection element 600 may be disposed on the second connection element 500 while being directly in contact with the second connection element 500, and may be electrically connected to the second connection element 500. The third connection element 600 may be, for example, a solder ball, but is not limited thereto. A shape of the third connection element 600 is duplicated with the description made with respect to the shape of the second connection element 500 and thus will be omitted below in the interest of brevity.

In some embodiments, a redistribution layer may be additionally disposed between the second connection element 500 and the third connection element 600. The redistribution layer may correspond to an insulating layer, but is not limited thereto. A plurality of redistribution patterns may be formed inside the redistribution layer. Each of the plurality of redistribution patterns may include a conductive material. For example, the plurality of redistribution patterns may include copper (Cu), but are not limited thereto.

The plurality of redistribution patterns may electrically connect the second connection element 500 with the third connection element 600. When the redistribution layer is additionally disposed between the second connection element 500 and the third connection element 600, an interval or spacing between the third connection elements 600 may be narrower than that between the second connection elements 500.

The second package 1000B may be disposed on the third connection element 600. The second package 1000B may include a second package substrate 100B and a second semiconductor chip 200B. The description of the second package substrate 100B, the second upper passivation layer 101B covering the surface of the second package substrate 100B, the second lower passivation layer 102B, the second wiring pattern 110B formed inside the second package substrate 100B, the second upper pad 111B, and the second lower pad 112B is duplicated with the description of the first package substrate 100A, the first upper passivation layer 101A, the first lower passivation layer 102A, the first wiring pattern 110A, the first upper pad 111A and the first lower pad 112A, and thus will be omitted below in the interest of brevity.

In some embodiments, the third connection element 600 may be formed on a lower surface of the second lower passivation layer 102B or a lower surface of the second lower pad 112B. The third connection element 600 may be attached to the second lower pad 112B. The third connection element 600 may electrically connect the second wiring pattern 110B with the second connection element 500. Therefore, the third connection element 600 may provide an electrical signal to the second wiring pattern 110B or provide the electrical signal provided from the second wiring pattern 110B to the second connection element 500.

In some embodiments, the second semiconductor chip 200B may be a memory chip such as a volatile memory (e.g., DRAM) or a non-volatile memory (e.g., ROM or flash memory). In addition, the second semiconductor chip 200B may be composed of a combination of the volatile memory and the non-volatile memory.

In some embodiments, the second semiconductor chip 200B may be mounted on the second package substrate 100B by a flip chip bonding method. For example, as shown in FIG. 2, the second semiconductor chip 200B may be electrically connected to the second package substrate 100B by a solder, bump or pillar-shaped connection element that includes a conductive material, but the disclosure is not limited thereto. The second semiconductor chip 200B may be mounted on the second package substrate 100B by a wire bonding method. In some embodiments, the second semiconductor chip 200B may be disposed so as not to overlap the first semiconductor chip 200A in a vertical perspective (e.g., Z-axis perspective). In other words, the second semiconductor chip 200B may be horizontally spaced apart from the first semiconductor chip 200A

In some embodiments, the second mold layer 300B covering at least a portion of the second semiconductor chip 200B and covering the second package substrate 100B may be formed on the second package substrate 100B. The second mold layer 300B may fill or be in a space between the second package substrate 100B and the second semiconductor chip 200B. Therefore, the second mold layer 300B may cover or be on the second package substrate 100B and the second semiconductor chip 200B. In the same manner as the first mold layer 300A, the second mold layer 300B may include an insulating polymer material such as an epoxy molding compound (EMC). The description of a material constituting the second mold layer 300B is duplicated with the description of the material constituting the first mold layer 300A, and thus will be omitted below in the interest of brevity.

As described above, in some embodiments, the first semiconductor chip 200A is disposed on the first region R1 of the first package substrate 100A, and the second connection element 500, the third connection element 600 and the second package 1000B are sequentially disposed on the second region R2 that does not overlap the first region R1, so that a side-by-side stack package structure may be implemented.

Unlike a package-on-package structure, in the side-by-side stack package structure, two or more semiconductor chips are disposed in parallel, so that a total thickness of the semiconductor package may be reduced. Also, in some embodiments, when the first semiconductor chip 200A is implemented as a logic chip such as AP chip or SOC and the second semiconductor chip 200B is implemented as a memory chip, a thickness of the logic chip having a relatively large amount of heat as compared with the memory chip may be increased, so that heat dissipation characteristics of the semiconductor package may be improved.

In some other embodiments, a portion of the second package 1000B may overlap the first semiconductor chip 200A in a vertical perspective. A width of the semiconductor package 1000 in X-axis direction is reduced, so that lightweight miniaturization may be realized.

In addition, the first mold layer 300A is uniformly formed on the first region R1 of the first package substrate 100A on which the first semiconductor chip 200A is disposed and the second region R2 of the first package substrate 100A on which the second package 1000B is disposed, so that warpage of the package substrate due to local formation of the mold layer may be avoided.

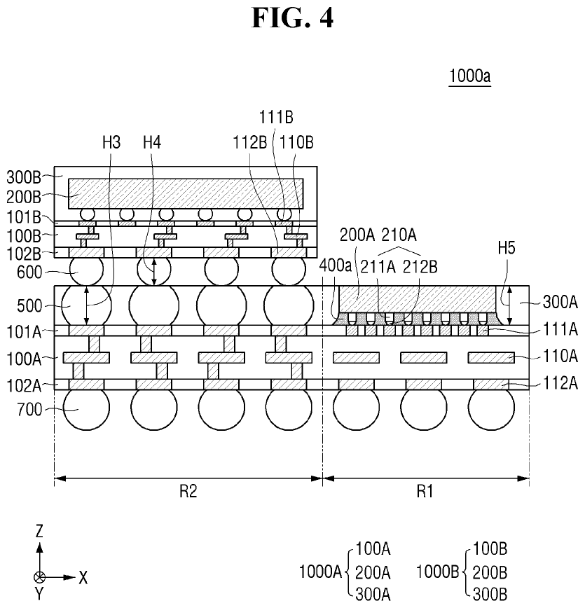

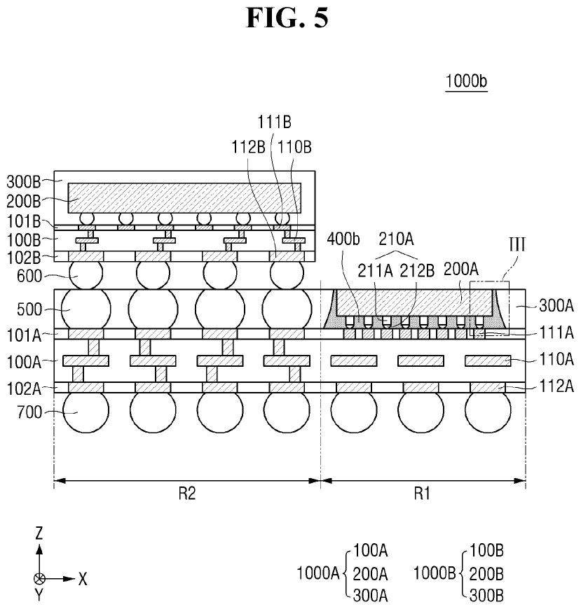

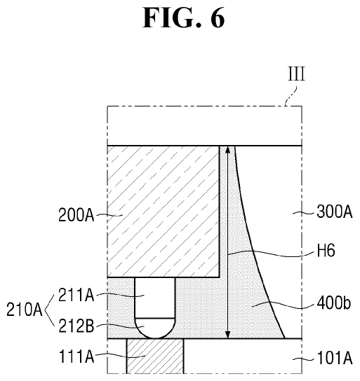

FIGS. 4 and 5 are example views illustrating a semiconductor package according to some embodiments. FIG. 6 is an enlarged view illustrating a portion III of FIG. 5.

First of all, referring to FIG. 4, in a semiconductor package 1000a according to some embodiments, an underfill layer 400a may be interposed between the first package substrate 100A and the first semiconductor chip 200A. The underfill layer 400a may fill or be in a space between the upper surface of the first upper passivation layer 101A and the lower surface of the first semiconductor chip 200A. The underfill layer 400a may cover or be on the first connection element 210A. The underfill layer 400a may prevent the first semiconductor chip 200A from being broken by fixing the first semiconductor chip 200A onto the first package substrate 100A. The underfill layer 400a may include, for example, an insulating polymer material such as an epoxy molding compound (EMC), but is not limited thereto.

Next, referring to FIG. 5, in a semiconductor package 1000b according to some embodiments, an underfill layer 400b may be formed to cover or surround the side of the first semiconductor chip 200A, unlike FIG. 4. In this way, when the underfill layer 400b is formed to cover the side of the first semiconductor chip 200A due to its large amount, a portion of an upper surface portion of the underfill layer 400b may be ground together with a portion of the upper surface portion of the first semiconductor chip 200A and the first mold layer 300A when the first mold layer 300A and a portion of the upper surface portion of the first semiconductor chip 200A are ground.

In this case, an upper surface of the underfill layer 400b may be coplanar with the upper surface of the first semiconductor chip 200A, the upper surface of the first mold layer 300A and the upper surface of the second connection element 500. Also, referring to FIG. 6, a height H6 of the underfill layer 400b may be the same as a sum of the height H1 of the first connection element 210A and the height of the first semiconductor chip 200A. The height H6 of the underfill layer 400b may be the same as the height H3 of the second connection element 500 and the height H5 of the first mold layer 300A (see H5 in FIG. 4).

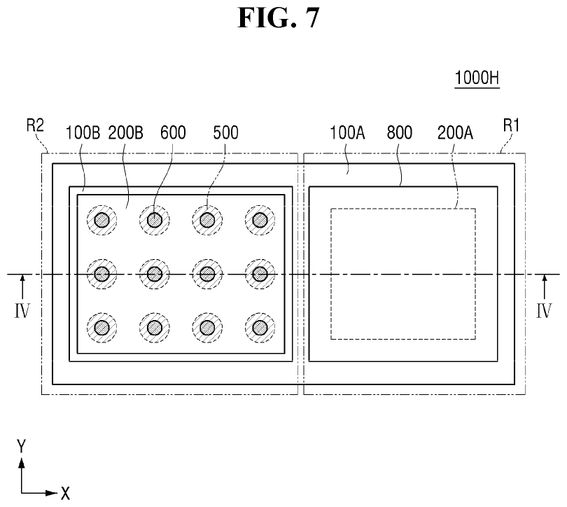

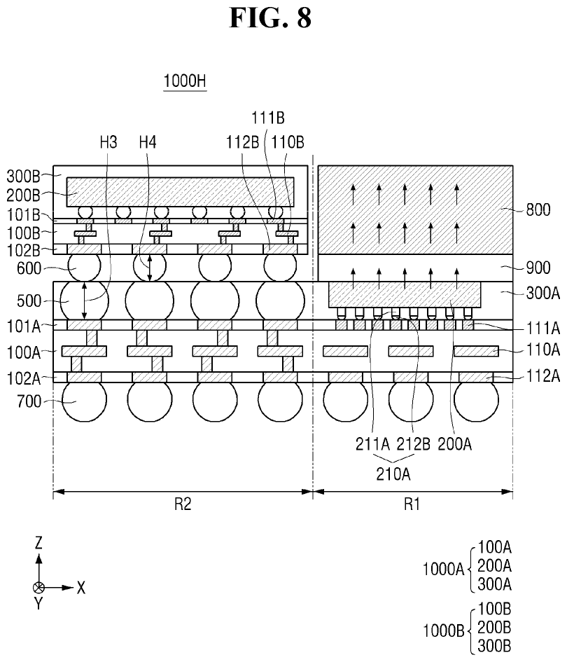

FIG. 7 is an example plan view illustrating a semiconductor package according to some embodiments. FIG. 8 is a cross-sectional view taken along line IV-IV of FIG. 7. Hereinafter, in the interest of brevity, the description duplicated with the aforementioned description will be omitted, and the following description will be based on differences.

Referring to FIGS. 7 and 8 together, a semiconductor package 1000H according to some embodiments may further include a heat slug 800 disposed on the upper surface of the first semiconductor chip 200A. The heat slug 800 may be of a metal material having high heat conductivity, such as copper and aluminum, but is not limited thereto.

In some embodiments, a thermal interface material (TIM) 900 may be disposed between the first semiconductor chip 200A and the heat slug 800. Since the TIM 900 includes particles having high heat conductivity, heat may be efficiently transferred from the first semiconductor chip 200A to the heat slug 800. The TIM 900 may be comprised of silica and an adhesive. An adhesive, e.g., a die attach film (DAF) may be coated on a lower surface of the TIM 900, so that the TIM 900 may be attached to the upper surface of the first semiconductor chip 200A.

In some embodiments, an upper surface of the heat slug 800 and an upper surface of the second mold layer 300B may be coplanar with each other. Therefore, an additional heat diffusion structure for improving heat dissipation characteristics of the semiconductor package may be disposed on the upper surfaces of the heat slug 800 and the second package 1000B.

In some embodiments, a portion of the second package 1000B may overlap the first semiconductor chip 200A in a vertical perspective. That is, a portion of the second package 1000B may be positioned on or above the first region R1. The heat slug 800 may be disposed in a region of the upper surface of the first semiconductor chip 200A, which does not overlap the second package 1000B. Therefore, a width of the semiconductor package 1000H in the X-axis direction may be reduced to realize lightweight and miniaturization and improve heat dissipation characteristics of the semiconductor package 1000H.

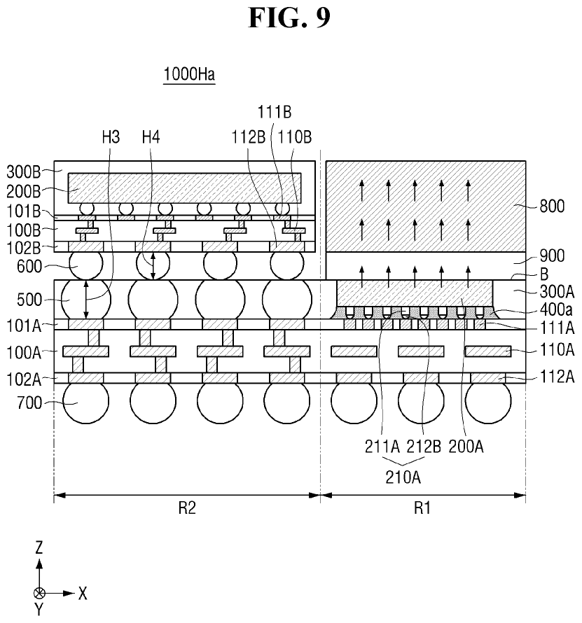

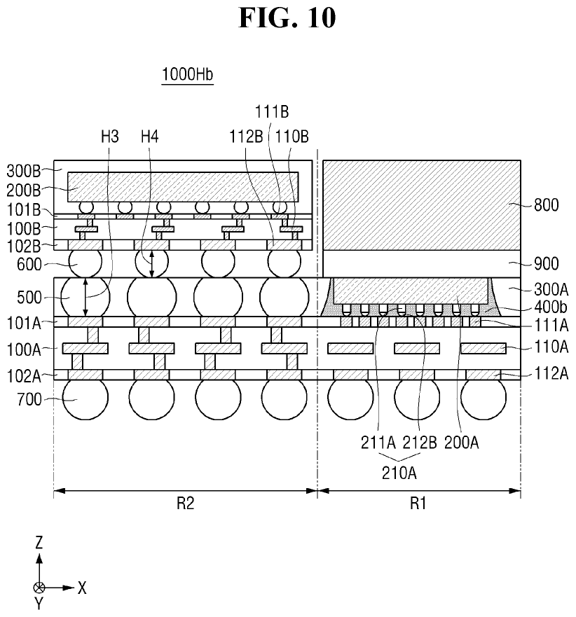

FIGS. 9 and 10 are example views illustrating a semiconductor package according to some embodiments.

First of all, referring to FIG. 9, in a semiconductor package 1000Ha according to some embodiments, a TIM 900 and a heat slug 800 may be sequentially disposed on an upper surface of a first semiconductor chip 200A in a structure (shown in FIG. 4) in which an underfill layer 400a is interposed between a first package substrate 100A and the first semiconductor chip 200A. Then, referring to FIG. 10, in a semiconductor package 1000Hb according to some embodiments, in the same manner as the structure (shown in FIG. 5) in which an underfill layer 400b is formed to cover or surround a side of the first semiconductor chip 200A, the TIM 900 and the heat slug 800 may be sequentially disposed on the upper surface of the first semiconductor chip 200A. Therefore, heat dissipation characteristics of the semiconductor package, which includes a semiconductor chip for generating a lot of heat, may be improved.

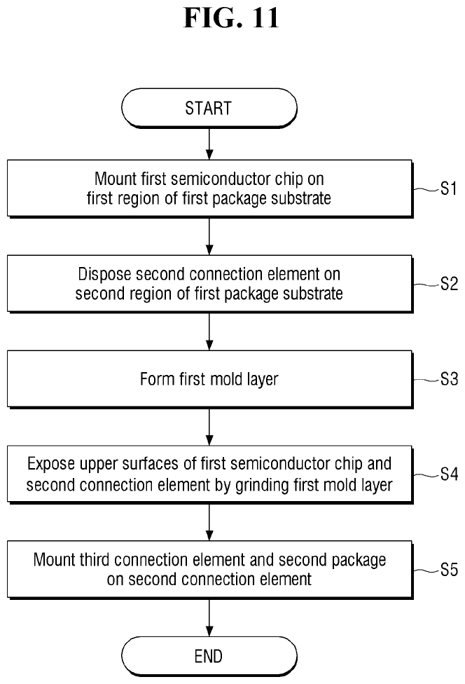

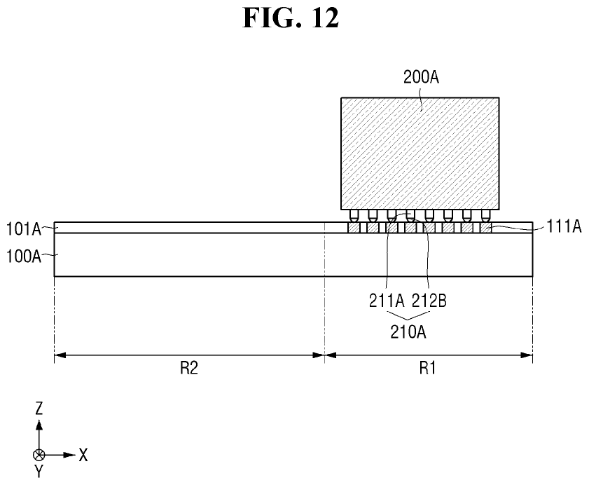

FIG. 11 is a flowchart illustrating a method of fabricating a semiconductor package according to some embodiments. FIGS. 12 to 19 are views illustrating intermediate steps to describe a method of fabricating a semiconductor package according to some embodiments. Hereinafter, a method of fabricating a semiconductor package according to some embodiments will be described with reference to FIGS. 11 to 19.

First of all, referring to FIGS. 11 and 12, a first semiconductor chip 200A is mounted on a first region R1 of a first package substrate 100A (S1). In some embodiments, the first semiconductor chip 200A may be mounted on the first package substrate 100A by a first connection element 210A formed between an upper surface of the first package substrate 100A and a lower surface of the first semiconductor chip 200A.

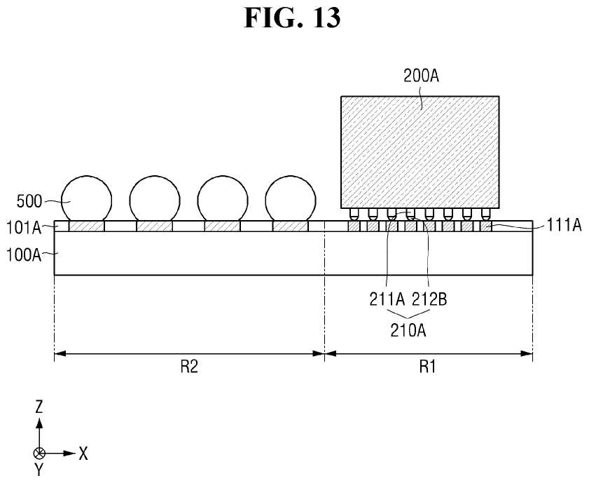

Then, referring to FIGS. 11 and 13, a second connection element 500 is disposed on a second region R2 of the first package substrate 100A that does not overlap the first region R1 (S2). In some embodiments, the second connection element 500 may be attached to a first upper pad 111A exposed by a first upper passivation layer 101A.

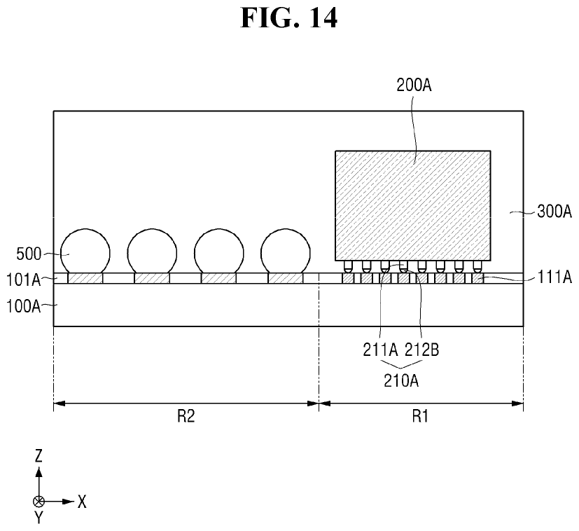

Next, referring to FIGS. 11 and 14, a first mold layer 300A covering at least a side or side surface of the first semiconductor chip 200A and the second connection element 500 is formed (S3). In some embodiments, the first mold layer 300A may cover both an upper surface and a side of the first semiconductor chip 200A, and may cover both an upper surface and a side of the second connection element 500.

In this way, the first mold layer 300A covering the first semiconductor chip 200A and the second connection element 500 and covering the first region R1 and the second region R2 of the first package substrate 100A is formed before a second package 1000B is mounted on the second connection element 500, so that warpage of the first package substrate 100A may be prevented from occurring.

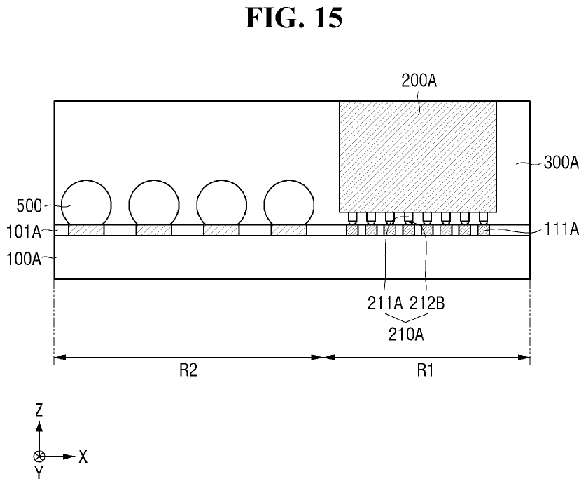

Referring to FIG. 15, unlike FIG. 14, in some embodiments, the first mold layer 300A may not cover the upper surface of the first semiconductor chip 200A. That is, when the first mold layer 300A is formed on the first package substrate 100A, the upper surface of the first semiconductor chip 200A may be exposed without being covered by the first mold layer 300A.

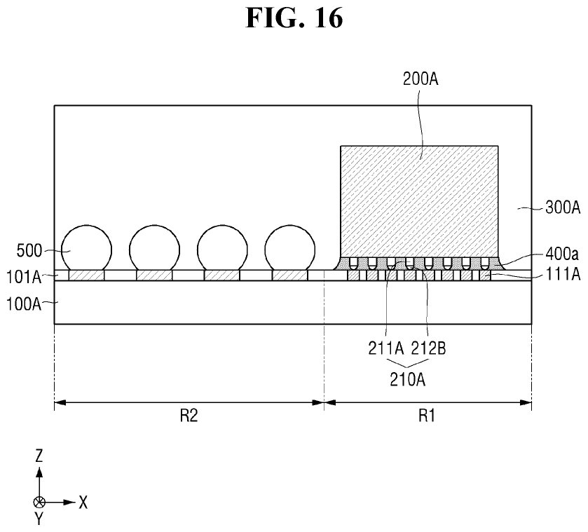

Referring to FIG. 16, unlike FIGS. 14 and 15, in some embodiments, before forming the first mold layer 300A, an underfill layer 400a filling a space between the first package substrate 100A and the first semiconductor chip 200A may be formed. For example, when a height H1 of the first connection element 210A is too low so that the space between the first package substrate 100A and the first semiconductor chip 200A cannot be filled with the first mold layer 300A, the spaced between the first package substrate 100A and the first semiconductor chip 200A may be filled with the underfill layer 400a.

Referring to FIGS. 11 and 17, the first mold layer 300A is ground using a grinding tool 910 such as a diamond wheel or a cutter to expose the upper surfaces of the first semiconductor chip 200A and the second connection element 500 (S4). In this case, a portion of the upper surface portion of the first semiconductor chip 200A and a portion of the upper surface portion of the second connection element 500 may be grinded together with the first mold layer 300A. In this way, a portion of the upper surface portion of the second connection element 500 covered with the first mold layer 300A is ground to expose the upper surface of the second connection element 500, so that the second connection element 500 may serve as a connection structure and a support structure, which are capable of packaging the second package 1000B on the upper surface thereof.

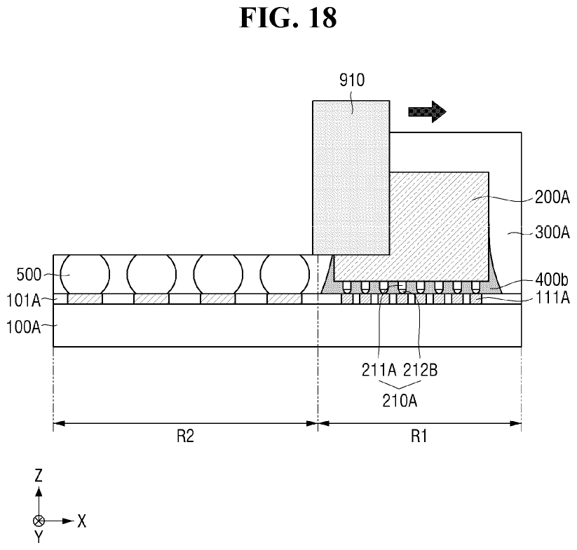

Referring to FIG. 18, in some embodiments, when a large amount of underfill layer 400b is formed before the first mold layer 300A is formed (shown in FIG. 5), a portion of the underfill layer 400b may be ground together with the first mold layer 300A and the first semiconductor chip 200A.

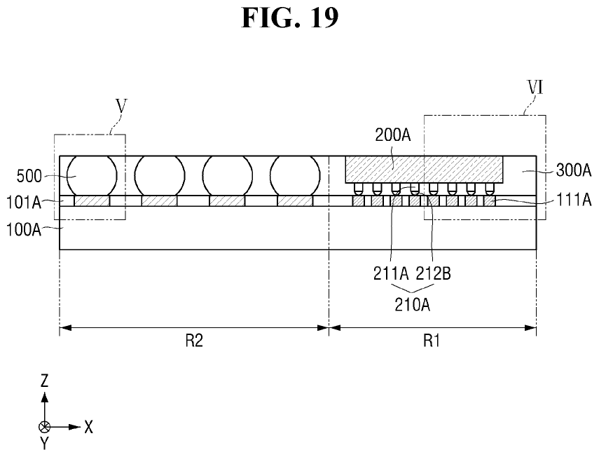

Referring to FIG. 19, in some embodiments, after grinding is completed, the upper surface of the first semiconductor chip 200A and the upper surface of the first mold layer 300A may be coplanar with each other. Also, the upper surface of the second connection element 500 and the upper surface of the first mold layer 300A may be coplanar with each other.

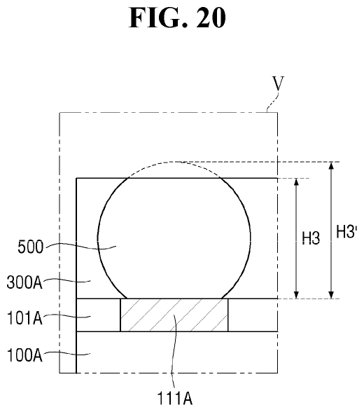

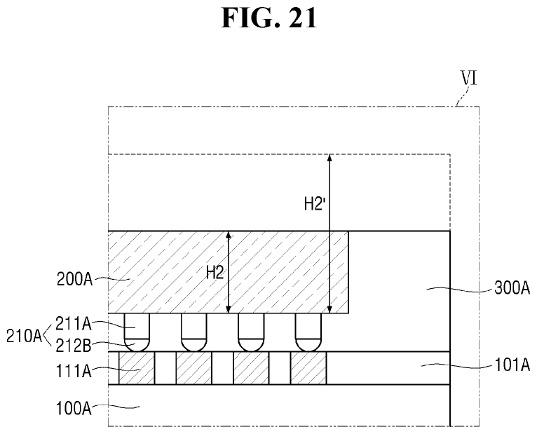

FIG. 20 is an enlarged view illustrating a portion V of FIG. 19. FIG. 21 is an enlarged view illustrating a portion VI of FIG. 19.

First of all, referring to FIG. 20, in some embodiments, a ratio of a height H3 of the second connection element 500 after grinding to a height H3′ of the second connection element 500 before grinding may be 80/100 to 90/100. H3/H3′ should be 80/100 or more so that the third connection element 600 and the second package 1000B may be stably disposed on the second connection element 500. For example, when H3/H3′ is smaller than 80/100, the size of the second connection element 500 remaining after grinding is too small, whereby the third connection element 600 and the second package 1000B may not be stably stacked on the second connection element 500.

In addition, H3/H3′ should be 90/100 or less, so that the upper surface of the second connection element 500 is sufficiently exposed, whereby the second connection element 500 and the third connection element 600 may be electrically connected to each other. For example, when H3/H3′ is greater than 90/100 as the upper surface portion of the second connection element 500 is not sufficiently ground, whereby the second connection element 500 and the third connection element 600 may not be electrically connected to each other. In some embodiments, the height H3 of the second connection element 500 after grinding may be 88 μm or more. This will be described below with reference to FIG. 21.

Referring to FIG. 21, in some embodiments, a ratio of a height H2 of the first semiconductor chip 200A after grinding to a height H2′ of the first semiconductor chip 200A before grinding may be 50/800 or more. For example, when H2/H2′ is smaller than 50/800, the size of the first semiconductor chip 200A remaining after grinding is too small, so that the first semiconductor chip 200A may lose its function. Also, in some embodiments, a height H1a of the pillar layer 211A may be 15 μm, a height H1b of the solder layer 212B may be 23 μm (see, e.g., FIG. 3), and the height H2 of the first semiconductor chip 200A after grinding may be 50 μm or more. When the height H2 of the first semiconductor chip 200A after grinding is smaller than 50 μm, the size of the first semiconductor chip 200A is too small, whereby the first semiconductor chip 200A may lose its function. The height H3 of the second connection element 500 after grinding may be 88 μm or more.

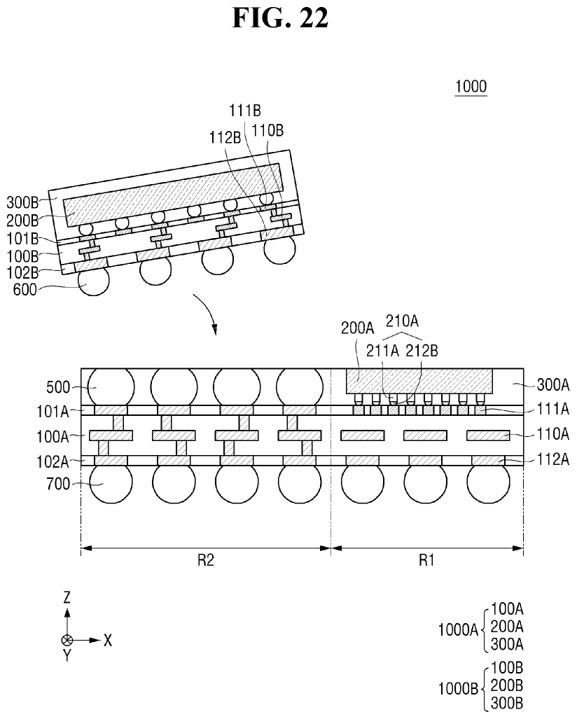

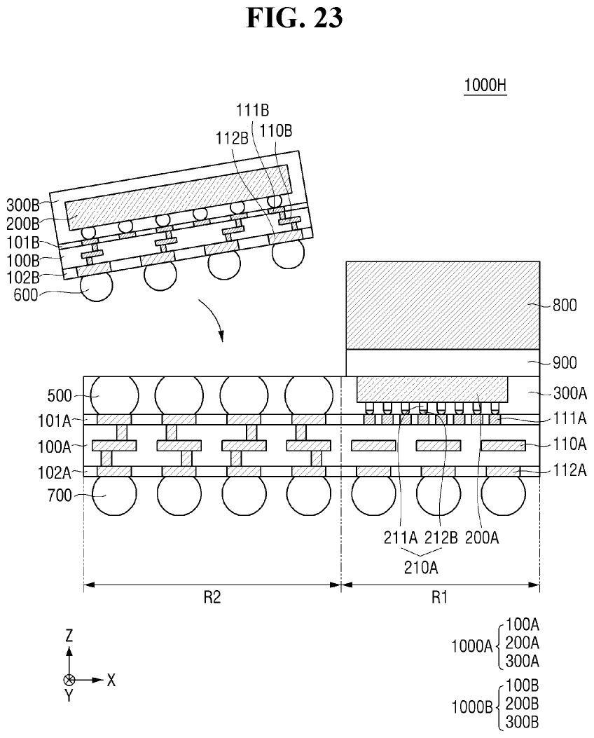

FIGS. 22 and 23 are views illustrating intermediate steps to describe a method of fabricating a semiconductor package according to embodiments. Hereinafter, a method of fabricating a semiconductor package according to some embodiments will be described with reference to FIGS. 11, 22 and 23.

First of all, referring to FIGS. 11 and 22, a third connection element 600 and a second package 1000B are mounted on a second connection element 500 (S5). In detail, a second semiconductor chip 200B is mounted on a second package substrate 100B, and the third connection element 600 is attached to a lower surface of the second package substrate 100B. In this case, the third connection element 600 may be attached onto a second lower pad 112B formed on the lower surface of the second package substrate 100B. Afterwards, the second package 1000B to which the third connection element 600 is attached may be mounted on the exposed second connection element 500, and the second connection element 500 and the third connection element 600 may be connected to each other through a reflow process. For example, in a state that the second package 1000B to which the third connection element 600 is attached is disposed on the exposed upper surface of the second connection element 500, the second connection element 500 and the third connection element 600 may be connected to each other by fusion by applying heat of about 180° C. to 240° C., for example. As a result, a side-by-side stack package in which the first semiconductor chip 200A and the second semiconductor chip 200B are disposed in parallel in view of a plane may be fabricated.

In some other embodiments, before the third connection element 600 and the second package 1000B are mounted on the second connection element 500, a redistribution layer may be further formed between the second connection element 500 and the third connection element 600. A plurality of redistribution patterns, which include a conductive material, may be formed inside the redistribution layer to electrically connect the second connection element 500 with the third connection element 600.

Also, in some embodiments, when the second package 1000B to which the third connection element 600 is attached is mounted, a portion of the second package 1000B may be disposed to overlap the first semiconductor chip 200A in a vertical perspective. At this time, the redistribution layer may be formed between the second connection element 500 and the third connection element 600 to electrically connect the second connection element 500 with the third connection element 600.

Next, referring to FIG. 23, in some embodiments, a heat slug 800 may be disposed on the upper surface of the first semiconductor chip 200A before the third connection element 600 and the second package 1000B are mounted on the second connection element 500. A TIM 900, which includes an adhesive such as DAF, may be disposed on the upper surface of the first semiconductor chip 200A, and the heat slug 800 may be disposed on an upper surface of the TIM 900. Alternatively, in some embodiments, the TIM 900, which includes an adhesive such as DAF, may be disposed on a lower surface of the heat slug 800, and the heat slug 800 in which the TIM 900 is disposed on the lower surface may be disposed on the upper surface of the first semiconductor chip 200A.

In some embodiments, the heat slug 800 may be disposed to cover only a portion of the upper surface of the first semiconductor chip 200A, unlike the example shown in FIG. 23. Also, a portion of the second package 1000B may be disposed in a region of the upper surface of the first semiconductor chip 200A, which does not overlap the heat slug 800.

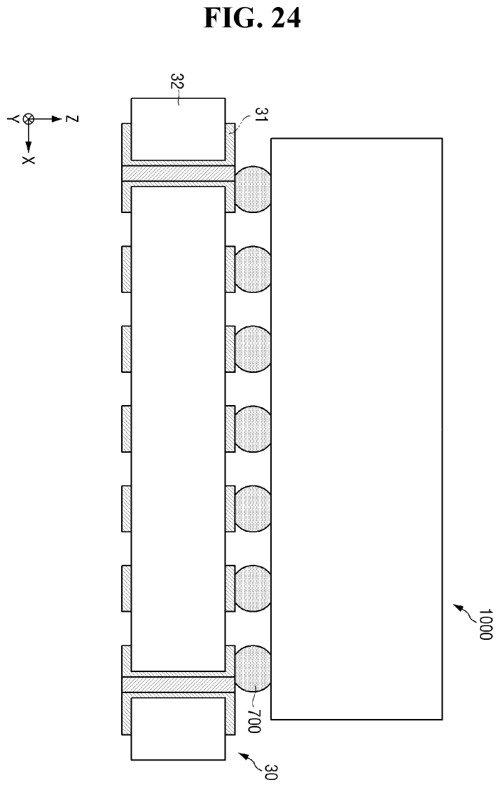

FIG. 24 is a view illustrating a semiconductor package and a main board according to some embodiments.

Referring to FIG. 24, a semiconductor package 1000 according to some embodiments may be disposed on a main board 30. In some embodiments, the semiconductor package 1000 may correspond to a semiconductor package 1000 (shown in FIG. 1), a semiconductor package 1000a (shown in FIG. 4), a semiconductor package 1000b (shown in FIG. 5), a semiconductor package 1000H (shown in FIG. 7), a semiconductor package 1000Ha (shown in FIG. 9), a semiconductor package 1000Hb (shown in FIG. 10). For example, a connection structure 700 may be disposed on the main board 30. The main board 30 may be connected to the semiconductor package 1000 by the connection structure 700.

The main board 30 may be a printed circuit wiring structure (or printed circuit board (PCB)), a ceramic wiring structure, a glass wiring structure and an interposer wiring structure, but the present disclosure is not limited thereto. For convenience of description, it is assumed that the main board 30 is a printed circuit wiring structure.

The main board 30 may include a connection structure 31 and a core 32. The core 32 may include a copper clad laminate (CCL), a Prepreg (PPG), an Ajinomoto Build-up Film (ABF), epoxy, polyimide and the like. The connection structure 31 may include at least one of copper (Cu), aluminum (Al), silver (Ag), tin (Sn), gold (Au), nickel (Ni), lead (Pb), titanium (Ti) or their alloy, but is not limited thereto.

The core 32 may be disposed at the center of the main board 30, and the connection structure 31 may be disposed at upper and lower portions of the core 32. The connection structure 31 may be disposed to be exposed to upper and lower portions of the main board 30.

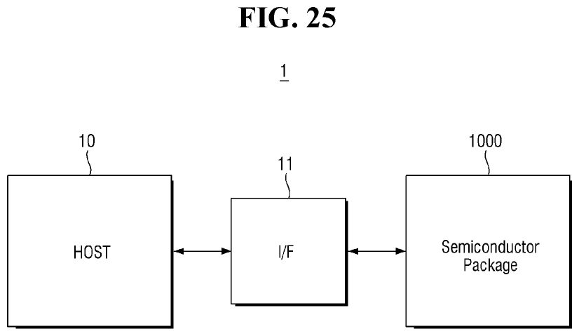

The connection structure 31 may be also disposed to pass through the core 32. The connection structure 31 may electrically connect elements, which are in contact with the main board 30, with each other. For example, the connection structure 31 may electrically connect the semiconductor package 1000 with a host 10 (shown in FIG. 25). That is, the connection structure 31 may electrically connect the semiconductor package 1000 with the host 10 (shown in FIG. 25) through the connection structure 700.

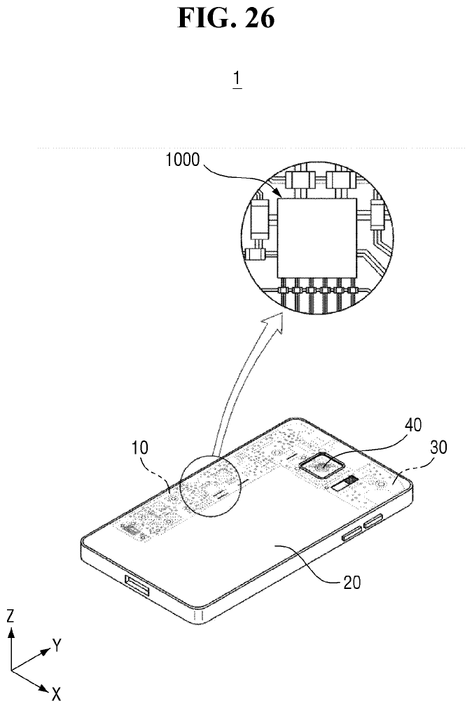

FIGS. 25 and 26 are views illustrating an electronic device including a semiconductor package according to some embodiments.

Referring to FIG. 25, an electronic device 1 may include a host 10, an interface 11 and a semiconductor package 1000.

In some embodiments, the host 10 may be connected with the semiconductor package 1000 through the interface 11. For example, the host 10 may transfer a signal to the semiconductor package 1000 to control the semiconductor package 1000. For example, the host 10 may receive the signal from the semiconductor package 1000 to process data included in the signal.

For example, the host 10 may include a central processing unit (CPU), a controller or an application specific integrated circuit (ASIC). In addition, for example, the host 10 may include a memory chip such as a dynamic random access memory (DRAM), a static RAM (SRAM), a phase-change RAM (PRAM), a magneto-resistive RAM (MRAM), a ferroelectric RAM (FeRAM) and a resistive RAM (RRAM).

Referring to FIGS. 25 and 26, the electronic device 1 may include a host 10, a body 20, a main board 30, a camera module 40 and a semiconductor package 1000.

The main board 30 may be mounted in the body 20 of the electronic device 1. The host 10, the camera module 40 and the semiconductor package 1000 may be mounted on the main board 30. The host 10, the camera module 40 and the semiconductor package 1000 may be electrically connected to one another by the main board 30. For example, the interface 11 may be implemented by the main board 30.

The host 10 and the semiconductor package 1000 may be electrically connected to each other by the main board 30 to transmit and receive a signal to and from each other.

While the present disclosure has been particularly illustrated and described with reference to example embodiments thereof, it will be understood by those of ordinary skill in the art that various changes in form and detail may be made therein without departing from the scope of the present disclosure as defined by the following claims. The example embodiments should be considered in a descriptive sense only and not for purposes of limitation.

What is claimed is:

1. A semiconductor package comprising:
a first package substrate having a first region and a second region, which do not overlap each other;
a first connection element having a first height on the first region;
a first semiconductor chip having a second height connected to the first connection element;
a second connection element having a third height on the second region;
a third connection element having a fourth height on the second connection element and electrically connected to the second connection element;
a second package on the third connection element, the second package including a second package substrate and a second semiconductor chip; and
a first mold layer covering at least a portion of the first semiconductor chip, covering at least a portion of the second connection element, covering at least a portion of the first package substrate, exposing an upper surface of the first semiconductor chip and an upper surface of the second connection element, and having a fifth height.

2. The semiconductor package of claim 1, further comprising a heat slug on the upper surface of the first semiconductor chip.

3. The semiconductor package of claim 2, further comprising a thermal interface material (TIM) between the first semiconductor chip and the heat slug.

4. The semiconductor package of claim 2, further comprising a second mold layer covering at least a portion of the second semiconductor chip and at least a portion of the second package substrate.

5. The semiconductor package of claim 4, wherein an upper surface of the second mold layer and an upper surface of the heat slug are coplanar with each other.

6. The semiconductor package of claim 1, further comprising an underfill layer between the first package substrate and the first semiconductor chip.

7. The semiconductor package of claim 1, wherein the upper surface of the first semiconductor chip and an upper surface of the first mold layer are coplanar with each other.

8. The semiconductor package of claim 7, wherein the upper surface of the second connection element and the upper surface of the first mold layer are coplanar with each other.

9. The semiconductor package of claim 1, wherein the third height of the second connection element is equal to a sum of the first height of the first connection element and the second height of the first semiconductor chip.

10. A semiconductor package comprising:
a first package substrate;
a first semiconductor chip on the first package substrate;
a first connection element horizontally spaced apart from the first semiconductor chip and on the first package substrate;
a second connection element on the first connection element and electrically connected to the first connection element;
a second package on the second connection element, the second package including a second package substrate and a second semiconductor chip; and
a mold layer on the first package substrate and exposing an upper surface of the first semiconductor chip and an upper surface of the first connection element,
wherein the second semiconductor chip does not vertically overlap the first semiconductor chip.

11. A method of fabricating a semiconductor package, the method comprising:
mounting a first semiconductor chip on a first region of a first package substrate;
positioning a first connection element on a second region of the first package substrate that is separate from the first region,
forming a first mold layer covering at least a side of the first semiconductor chip and at least a side of the first connection element;
exposing an upper surface of the first semiconductor chip and an upper surface of the first connection element by grinding the first mold layer; and
mounting, on the first connection element, a second connection element electrically connected to the first connection element and a second package which is electrically connected to the second connection element and includes a second package substrate and a second semiconductor chip.

12. The method of claim 11, further comprising positioning a heat slug on the upper surface of the first semiconductor chip before mounting the second connection element and the second package.

13. The method of claim 12, further comprising positioning a thermal interface material (TIM) between the first semiconductor chip and the heat slug.

14. The method of claim 11, further comprising forming an underfill layer in a space between the first package substrate and the first semiconductor chip before forming the first mold layer.

15. The method of claim 11, wherein a portion of the first connection element is ground together with the first mold layer when the first mold layer is ground.

16. The method of claim 15, wherein a height of the first connection element before grinding is A and a height of the first connection element after grinding is B, and 80/100≤B/A≤90/100.

17. The method of claim 16, wherein the height of the first connection element after grinding is 88 μm or more.

18. The method of claim 11, wherein a portion of the first semiconductor chip is ground together with the first mold layer when the first mold layer is ground.

19. The method of claim 18, wherein a height of the first semiconductor chip before grinding is A and a height of the first semiconductor chip after grinding is B, and B/A is 50/800 or more.

20. The method of claim 19, wherein the height of the first semiconductor chip after grinding is 50 μm or more.
